(19) United States
(12) Patent Application Publication
(10) Pub. No.: US 2010/0155795 A1
(43) Pub. Date: Jun. 24, 2010

(54) SEMICONDUCTOR DEVICE AND METHOD FOR MANUFACTURING THE SAME

(76) Inventor: YONG SOO CHO, Daejeon (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/634,016

(22) Filed: Dec. 9, 2009

(30) Foreign Application Priority Data
Dec. 23, 2008 (KR) 10-2008-0132111

(51) Int. Cl. H01L 29/78; H01L 21/336

(52) U.S. Cl. 257/288; 438/302; 257/E29.255; 257/E21.437

(57) ABSTRACT

A semiconductor device according to an embodiment includes: a substrate on which a source/drain region is formed; a gate oxide that includes a first oxide formed on the substrate and implanted with fluorine impurity, and a second oxide formed on the first oxide; a gate electrode that is formed on the gate oxide; and a spacer that is formed on a side of the gate electrode.

### CROSS-REFERENCE TO RELATED APPLICATION

This application claims the benefit under 35 U.S.C. §119 of Korean Patent Application No. 10-2008-0132111, filed Dec. 23, 2008, which is hereby incorporated by reference in its entirety.

### BACKGROUND

As a semiconductor device becomes highly integrated, a line width of patterns configuring the semiconductor device and an interval between the patterns have been remarkably narrowed. With the reduction of the line width of the pattern, that is, the design rule, a channel length of the transistor is reduced.

With the advancement of this technology, the channel density is increased, which degrades mobility and leads to the reduction of MOSFET performance. In order to improve the MOSFET performance, efforts to improve the mobility on a channel surface has been continued.

In the related art, NH₃— is generated by the combination of nitrogen and hydrogen at the interface of silicon and a gate oxide. In this case, holes are trapped in the channel, thereby degrading the performance of the semiconductor device.

### BRIEF SUMMARY

An embodiment of the present invention provides a semiconductor device capable of reducing the generation of NH₃— at an interface of silicon and a gate oxide, by combining hydrogen and fluorine at the time of forming the gate oxide and a method for manufacturing the same.

A semiconductor device according to an embodiment includes: a substrate on which a source/drain region is formed; a gate oxide comprising a first oxide formed on the substrate and implanted with fluorine impurity, and a second oxide formed on the first oxide; a gate electrode formed on the gate oxide; and a spacer formed on a side of the gate electrode.

A method for manufacturing a semiconductor device according to an embodiment includes: forming a first oxide on a substrate; implanting impurity into the first oxide; forming a gate oxide configured to include the first oxide and a second oxide formed on the first oxide; forming a gate electrode on the gate oxide; forming a first source/drain region by implanting impurity into the substrate; forming a spacer on a side of the gate electrode; and forming a source/drain region having an LDD structure by forming a second source/drain region beneath the first source/drain region.

With embodiments of the above-mentioned semiconductor device and method for manufacturing the same, the combination of hydrogen and nitrogen at the interface of the silicon and the gate oxide is reduced and thus, the efficient channel movement of the holes can be achieved.

### BRIEF DESCRIPTION OF THE DRAWINGS

FIG. 1 is a diagram showing a semiconductor device according to an embodiment.

FIGS. 2 to 6 are diagrams showing a method for manufacturing a semiconductor device according to an embodiment.

### DETAILED DESCRIPTION

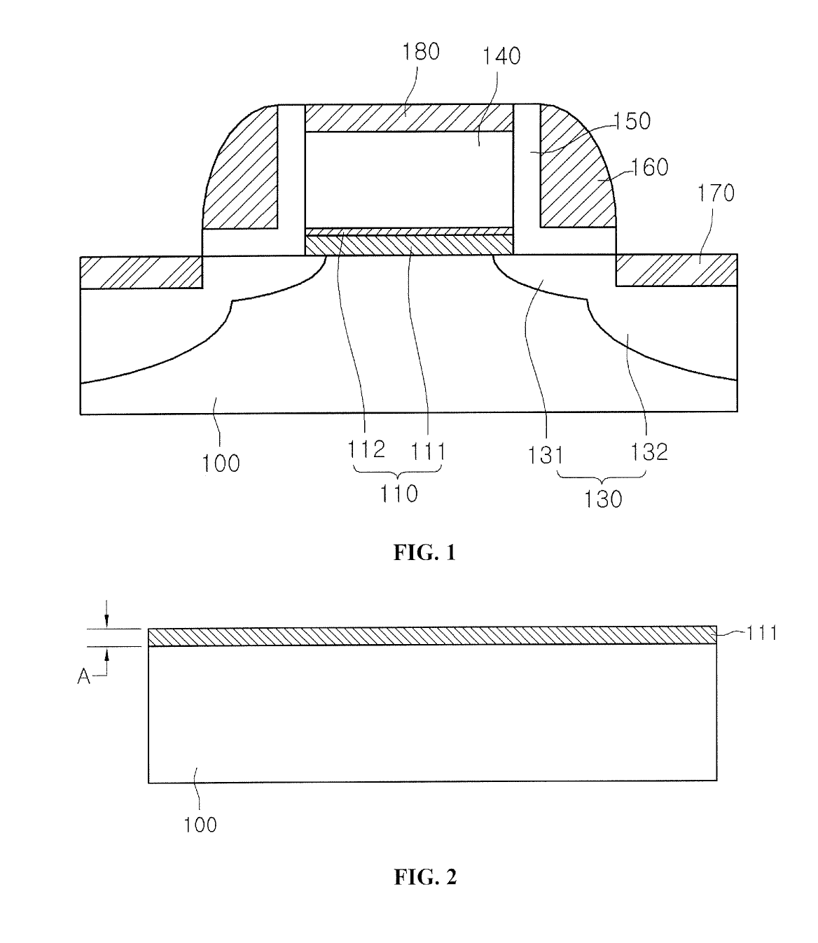

Referring to FIG. 1, a semiconductor device can include a gate oxide 110 and a gate electrode 140 formed on a substrate 100, and a source/drain region with a lightly doped drain (LDD) structure 130 having a shallow source/drain region 131 and a deep source/drain region 132.

The gate oxide 110 is configured to include a first oxide 111 that is implanted with fluorine impurity, and a second oxide 112 that is formed on the first oxide 111 and is not implanted with the fluorine impurity.

In particular, the first oxide 111, which is implanted with fluorine impurity, contacts a silicon surface. Accordingly, compounds, in which hydrogen and nitrogen are combined, do not occur at the interface of the gate oxide 110 and the silicon by using the fluorine impurity implanted in the first oxide 111 even though subsequent processes are progressed. In other words, the amount of hydrogen, which can be combined with nitrogen at the substrate, can be largely reduced at the gate oxide 110, in particular, the first gate oxide 110 contacting the substrate 100, such that the generation of compounds, in which hydrogen and nitrogen are combined, can be reduced at the interface of the substrate 100 and the gate oxide 110.

The thickness of the first oxide 111 occupies 80±10% of the entire thickness of the gate oxide 110, in consideration of a process of implanting fluorine in the first oxide 111.

The semiconductor device can further include spacers 140 and 150 having a double structure at sides of the gate electrode 140. A part of the first spacer 140 contacts the gate electrode 140 and other parts of the first spacer 140 are formed on the substrate 100. The second spacer 150 is formed on the part of first spacer 140 that is formed on the substrate 100 such that the first spacer 140 is also positioned on one side of the second spacer 150.

In addition, a silicide 170 can be formed on the source/drain region 130 and a silicide 180 can be formed on the gate electrode 140 to lower contact resistance.

Hereinafter, a method for manufacturing a semiconductor device having the above-mentioned structure will be described.

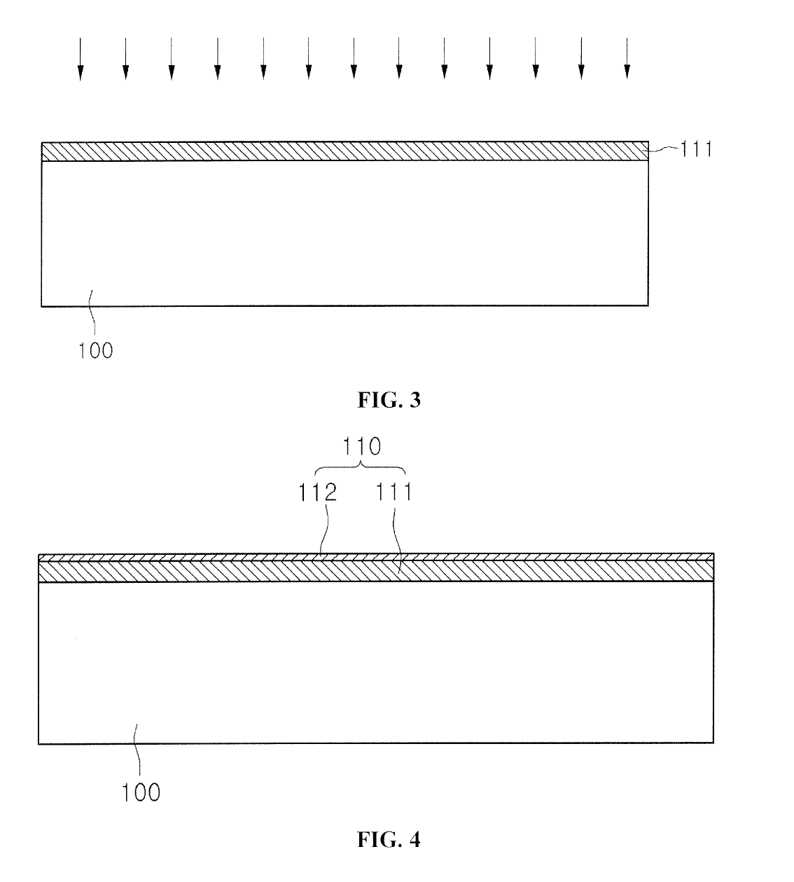

FIGS. 2 to 6 are diagrams showing a method for manufacturing a semiconductor device according to an embodiment.

Referring first to FIG. 2, a first oxide 111 of the gate oxide is deposited on a high voltage (HV) region of the substrate 100. Herein, the first oxide 111 is formed to have a thickness of the range of 80±10% with respect to a total thickness of a target (the gate oxide 110 shown FIG. 1).

For example, when the thickness A of the first oxide 111 is formed at 80% with respect the target, if the total thickness (gate oxide 110) of the target is 6.0 nm, the first oxide 111 will be formed at a thickness of 4.8 nm.

After the first oxide 111 is formed on the substrate of the high voltage region in consideration of the thickness of the target, an ion implantation process for implanting fluorine (F+) ion in the first oxide 111 is performed.

In other words, as shown in FIG. 2, the fluorine ion is implanted over the entire surface of the substrate. At this time, the peak concentration of the fluorine ion implantation conforms to the interface of the first oxide 111 and the silicon of the substrate 100, such that the fluorine ion can be evenly implanted in the first oxide contacting the surface of the substrate 100.

The fluorine ion implanting process is used without a mask and is performed on both NMOS and PMOS regions of a device.

Then, referring to FIG. 4, a second oxide 112 is formed on the first oxide 111 such that the final thickness of the gate oxide, which is the target, can be achieved. The second oxide 112 can be formed by performing a process of forming a further oxide on the first oxide 111 in which the fluorine ion is implanted. Therefore, it can be appreciated from the above description that the formation thickness of the second oxide 112 will have a value of the range of 20±10% with respect to the total thickness of the target.

Therefore, the gate oxide 110 configured of the first oxide 111 and the second oxide 112, which can be differentiated by the implantation or not of the fluorine ion and the formation thickness thereof, is formed as shown.

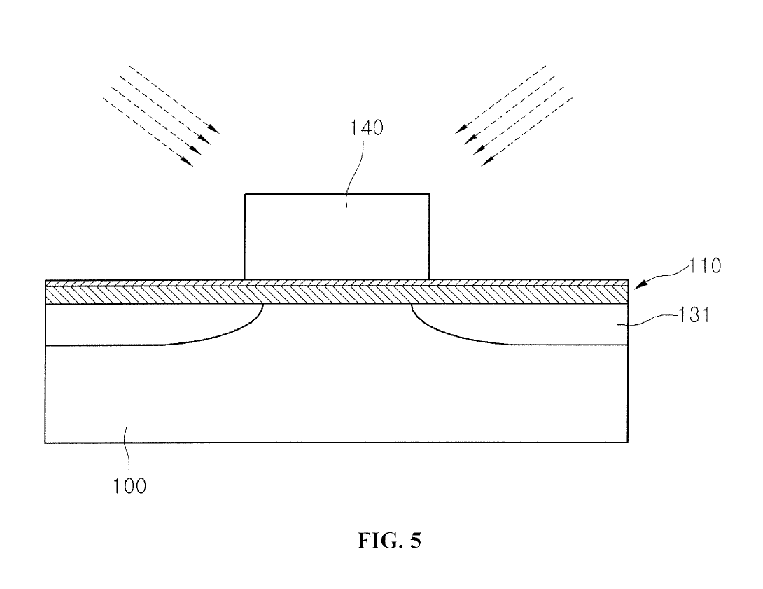

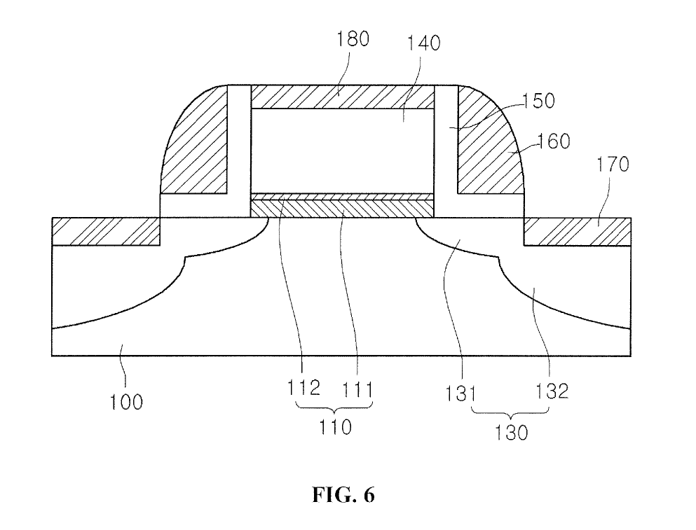

Thereafter, referring to FIG. 5, a polysilicon layer for forming the gate electrode is deposited on the gate oxide 110 and is then patterned, thereby forming the gate electrode 140 having the structure as shown.

At this time, the gate oxide 110 formed below the patterned gate electrode 140 is not yet patterned.

An ion implantation process is performed for forming the shallow source/drain region configuring the source/drain region having the LDD structure in the substrate 100.

In other words, the ion implantation process for forming the LDD region forms the shallow source/drain region 131 of the LDD in the substrate. The implantation process can use BF₂ impurity of the PMOS devices in order to increase the flourine (F+) ion implantation effect. For example, the impurity implantation process for forming the LDD can use the implantation angle of 30° or more while rotating the substrate 100 four times.

Thereby, the shallow source/drain region 131 having the LDD structure as shown is formed, and the fluorine ion implantation effect of the gate oxide 110 can be more increased.

Thereafter, referring to FIG. 6, the gate structure is formed by patterning the gate oxide 110.

A nitride layer and an oxide layer are sequentially formed on the gate electrode 140 and the substrate 100. At this time, a blanket etch is performed on the nitride layer and the oxide layer such that spacers 150 and 160 of a double structure as shown are formed.

An ion implantation process is performed in the substrate using the spacers 150 and 160 as an ion implantation mask, such that the deep source/drain region 132 is formed to contact the shallow source/drain region 131 and to be positioned below it. Thereby, the source/drain region of the LDD structure is formed.

A silicide process is performed on the source/drain region 130 and the upper surface of the gate electrode 140, thereby forming silicides 170 and 180 that can lower the contact resistance. Thereby, compounds, which can trap the movement of hole, are not formed at the interface of the gate oxide and the silicon, thereby making it possible to manufacture devices with the improved characteristics.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to utilize or combine such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a substrate on which a source/drain region is formed;
a gate oxide comprising a first oxide formed on the substrate and implanted with fluorine impurity, and a second oxide formed on the first oxide;
a gate electrode formed on the gate oxide; and
a spacer formed on a side of the gate electrode.

2. The semiconductor device according to claim 1, wherein the first oxide has a thickness of a range of 80±10% with respect to a total thickness of the gate oxide.

3. The semiconductor device according to claim 1, wherein the source/drain region is implanted with fluorine impurity.

4. A method for manufacturing a semiconductor device comprising:
forming a first oxide on a substrate;
implanting impurity in the first oxide;
forming a second oxide on the first oxide, the first oxide and the second oxide providing a gate oxide;
forming a gate electrode on the gate oxide;
forming a first source/drain region by implanting impurity in the substrate;
forming a spacer on a side of the gate electrode; and
forming a second source/drain region in the substrate deeper than the first source/drain region such that the first source/drain region and the second source/drain region provide a source/drain region with a lightly doped drain (LDD) structure.

5. The method according to claim 4, wherein the first oxide is formed to a thickness of 80±10% with respect to a total thickness of the gate oxide.

6. The method according to claim 4, wherein the implanting of the impurity in the first oxide comprises implanting fluorine ions in the first oxide.

7. The method according to claim 6, wherein the implanting of the fluorine ions is performed such that peak concentration of the fluorine ions conforms to an interface of the first oxide and the substrate.

8. The method according to claim 4, wherein the forming of the first source/drain region comprises implanting impurity using an inclined angle to the substrate while rotating the substrate.

9. The method according to claim 8, wherein the implanting of the impurity using the inclined angle to the substrate while rotating the substrate implants BF₂ ions while rotating the substrate four times.

10. The method according to claim 4, wherein the forming of the gate electrode comprises:
forming a polysilicon layer on the gate oxide; and
patterning the polysilicon layer;
wherein the forming of the first source/drain region is performed after patterning the polysilicon layer, and wherein the gate oxide is patterned to correspond to the patterned polysilicon layer after the forming of the first source/drain region.
